(19) United States
(12) Patent Application Publication
(10) Pub. No.: US 2025/0100107 A1
(43) Pub. Date: Mar. 27, 2025

(54) ELASTIC MEMBRANE, POLISHING HEAD, AND POLISHING METHOD

(71) Applicant: EBARA CORPORATION, Tokyo (JP)

(72) Inventors: Yuichi KATO, Tokyo (JP); Shingo TOGASHI, Tokyo (JP)

(21) Appl. No.: 18/885,188

(22) Filed: Sep. 13, 2024

(30) Foreign Application Priority Data
Sep. 22, 2023 (JP) 2023-158240

(51) Int. Cl. B24B 41/06; B24B 37/10

(52) U.S. Cl. CPC B24B 41/06; B24B 37/10

(57) ABSTRACT

An elastic membrane that can improve elasticity is disclosed. The elastic membrane has a pressing portion and a partition wall having a bulging structure.

### CROSS REFERENCE TO RELATED APPLICATION

This document claims priority to Japanese Patent Application No. 2023-158240 filed Sep. 22, 2023, the entire contents of which are hereby incorporated by reference.

### BACKGROUND

A precision required for each process in a manufacturing of recent semiconductor devices has already reached an order of several nm, and a chemical mechanical polishing (CMP) is no exception. In addition, with an increasing integration density of semiconductor integrated circuits, a miniaturization and multi-layering are accelerating.

Therefore, in order to realize such miniaturization and multi-layering, it is necessary to limit a variation in a film thickness after the CMP polishing to the order of several nm over an entire surface of the wafer.

A cause of the variation in a residual film thickness is a variation in a film formation on the wafer. For example, a process of forming a film on the wafer is performed using various film formation techniques such as plating, chemical vapor deposition (CVD), and physical vapor deposition (PVD). In these film formation techniques, the film may not be formed uniformly over the entire surface of the wafer. In recent years, the variation is also due to the variation in the thickness and a shape of the wafer itself, and it is required to flatten such wafers by the CMP process.

A conventional polishing head can independently change a pressing force in a radial direction of the wafer, so it is possible to control a film thickness profile in the radial direction of the wafer. However, since pressure chambers are arranged concentrically, it is not possible to control the pressing force in a circumferential direction of the wafer, and therefore it is not possible to control the film thickness profile in the circumferential direction. To address this issue, a method of dividing the pressure chambers in the circumferential direction is also considered.

When applying a pressure to the pressure chamber formed of an elastic membrane made of an elastic material commonly used in a CMP apparatus, the elastic membrane expands and comes into close contact with the wafer. With this configuration, the elastic membrane can transmit the pressure in the pressure chamber evenly to the wafer.

However, the elastic membrane has a large number of partition walls for forming the divided pressure chambers, and such the elastic membrane is difficult to stretch, particularly in a vicinity of the partition walls, and there is a risk that the pressure in the pressure chambers cannot be uniformly transmitted to the wafer.

### SUMMARY

Therefore, there are provided an elastic membrane and a polishing head that can improve elasticity.

There is provided a polishing method using an elastic membrane that can improve elasticity.

Embodiments, which will be described below, relate to an elastic membrane, a polishing head, and a polishing method.

In an embodiment, there is provided an elastic membrane applicable to a polishing head for polishing a substrate, comprising: a pressing portion configured to press against the substrate; and a partition wall having a bulging structure configured to form a pressurizing chamber for applying a pressing force to the pressing portion.

In an embodiment, the partition wall has a first wall portion and a second wall portion configured to form the bulge structure, and the first wall portion and the second wall portion have: a wide portion configured to be spaced apart from each other; and a clamp portion configured to be connected to the wide portion and be close to each other.

In an embodiment, the partition wall has a first wall portion and a second wall portion having a V-shaped cross-section configured to be close to each other toward the pressing portion, and the first wall portion and the second wall portion are connected to each other at the pressing portion.

In an embodiment, the partition wall has a first wall portion, a second wall portion, and a third wall portion having a Y-shaped cross section, and the third wall portion is connected to the first wall portion and the second wall portion, and extends from a connection portion between the first wall portion and the second wall portion toward the pressing portion.

In an embodiment, the partition wall has a first pressure chamber and a second pressure chamber arranged on both sides of the pressurizing chamber, and the pressurizing chamber is arranged above the first pressure chamber and the second pressure chamber.

In an embodiment, the elastic membrane has a peripheral wall constituting an outer shape of the elastic membrane, and the partition wall has a peripheral wall side wall portion being arranged adjacent to the peripheral wall and extending at an angle relative to the pressing portion.

In an embodiment, there is provided a polishing head comprising: an elastic membrane described above; and a head body configured to hold the elastic membrane.

In an embodiment, the head body comprises a partition wall holder configured to hold the partition wall, and at least a portion of the partition wall holder is arranged in the pressurizing chamber.

In an embodiment, the polishing head has a widthwise gap formed between the partition wall and the partition wall holder.

In an embodiment, there is provided a polishing method comprising: holding a substrate by an elastic membrane configured to press against the substrate; supplying a fluid to a pressure chamber formed by a pressing portion configured to press against the substrate, while holding the substrate, to press the substrate against a polishing pad; and supplying a fluid to a pressurizing chamber formed by a partition wall having a bulge structure, to apply a pressing force to the pressing portion.

In an embodiment, holding the substrate comprises supplying a fluid to the pressurizing chamber and forming a vacuum in the pressure chamber to form a suction space on a lower surface of the pressing portion and suck the substrate.

In an embodiment, the polishing method comprises, after polishing of the substrate, forming a vacuum in the pressurizing chamber and supplying a fluid to the pressure chamber to release the substrate from the elastic membrane.

In an embodiment, the partition wall has a first wall portion and a second wall portion configured to form the bulging structure, and the first wall portion and the second wall portion have: a wide portion configured to be spaced apart from each other; and a clamp portion configured to be connected to the wide portion and be close to each other.

In an embodiment, the partition wall has a first wall portion and a second wall portion having a V-shaped cross-section configured to be close to each other toward the pressing portion, and the first wall portion and the second wall portion are connected to each other at the pressing portion. In an embodiment, the partition wall has a first wall portion, a second wall portion, and a third wall portion having a Y-shaped cross section, and the third wall portion is connected to the first wall portion and the second wall portion, and extends from a connection portion between the first wall portion and the second wall portion toward the pressing portion.

In an embodiment, the elastic membrane has a peripheral wall constituting an outer shape of the elastic membrane, and the partition wall has a peripheral wall side wall portion being arranged adjacent to the peripheral wall and extending at an angle relative to the pressing portion.

The partition wall has a bulging structure that forms a pressurizing chamber, and this structure can improve the elasticity of the elastic membrane, particularly the elasticity of the pressing portion.

### BRIEF DESCRIPTION OF THE DRAWINGS

FIG. 1 is a schematic view showing an embodiment of a polishing apparatus;

FIG. 2 is an enlarged cross-sectional view showing an embodiment of a polishing head;

FIG. 3 is a plan view showing one embodiment of an elastic membrane;

FIG. 4 is a partial cross-sectional view taken along a line A-A in FIG. 3;

FIG. 5 is a partial cross-sectional view taken along a line B-B in FIG. 3;

FIG. 6 is a view showing another embodiment of the elastic membrane;

FIG. 7 is a view showing another embodiment of the elastic membrane;

FIG. 8A is a view showing an example of a partition wall mounted on a partition wall holder;

FIG. 8B is a view showing another example of the partition wall mounted on the partition wall holder;

FIG. 8C is a view showing a state in which the partition wall mounted on the partition wall holder is tilted;

FIG. 9 is a view showing another embodiment of the partition wall;

FIG. 10A is a view showing an embodiment of a peripheral wall of the elastic membrane;

FIG. 10B is a view showing another embodiment of the peripheral wall;

FIG. 11A is a view showing an operation of the polishing head to suction and hold a wafer;

FIG. 11B is a view showing an operation of the polishing head to suction and hold the wafer;

FIG. 12 is a view showing another embodiment of the elastic membrane; and

FIG. 13 is a view showing an operation of the polishing head to release the wafer W.

### DESCRIPTION OF EMBODIMENTS

Hereinafter, embodiments will be described with reference to the drawings. In the drawings described below, the same or corresponding components are denoted by the same reference numerals, and duplicated descriptions will be omitted. In the embodiments described below, the configuration of one embodiment that is not particularly described is the same as the other embodiments, so duplicated descriptions will be omitted.

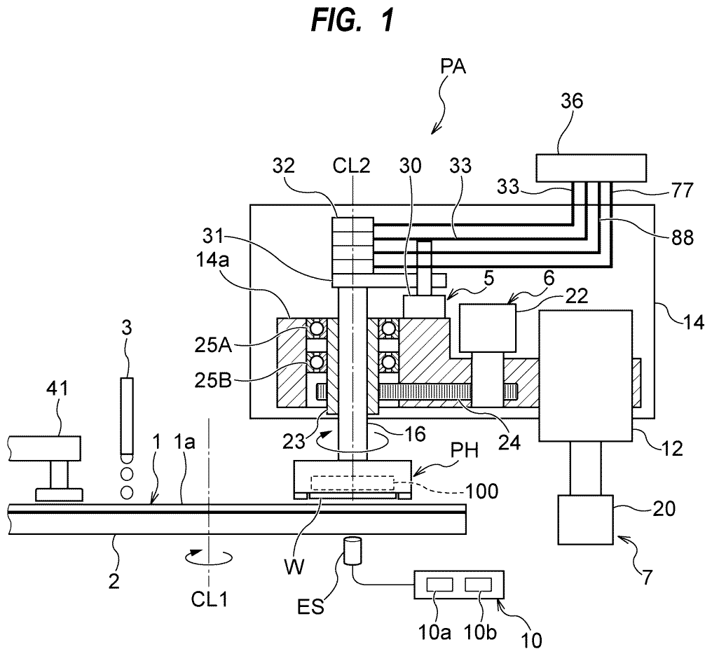

FIG. 1 is a schematic view showing an embodiment of a polishing apparatus. As shown in FIG. 1, the polishing apparatus PA includes a polishing head PH that holds and rotates a wafer W, which is an example of a substrate, a polishing table 2 that supports a polishing pad 1, a polishing liquid supply nozzle 3 that supplies a polishing liquid (slurry) onto a polishing surface 1a of the polishing pad 1, and a dresser 41 that dresses the polishing surface 1a of the polishing pad 1.

The polishing table 2 rotates about its central axis CL1. The polishing head PH rotates about its central axis CL2. The polishing table 2 and the polishing head PH rotate in the same direction (see FIG. 1), and in this state, the polishing head PH presses the wafer W against the polishing surface la of the polishing pad 1. The polishing liquid supply nozzle 3 supplies the polishing liquid onto the polishing surface 1a, and the wafer W is polished by sliding contact with the polishing pad 1 in a presence of the polishing liquid.

The polishing apparatus PA includes a head shaft 16 connected to the polishing head PH, a vertical movement mechanism 5 that moves the polishing head PH up and down via the head shaft 16, a rotary mechanism 6 that rotates the polishing head PH via the head shaft 16, and an oscillation arm 14 on which the vertical movement mechanism 5 and the rotary mechanism 6 are mounted.

The vertical movement mechanism 5 and the rotary mechanism 6 are supported by a support base 14a of the oscillation arm 14. The vertical movement mechanism 5 includes a vertical movement motor 30 and a coupling member 31 that couples the vertical movement motor 30 and the head shaft 16. The vertical movement motor 30 is a precision motor such as a servo motor. The vertical movement motor 30 moves the head shaft 16 up and down via the coupling member 31 by driving the vertical movement motor 30. The polishing head PH moves up and down together with the head shaft 16.

The rotary mechanism 6 includes a rotary motor 22, a rotary cylinder 23 attached to the head shaft 16 via a key (not shown), and a timing belt 24 stretched between the rotary motor 22 and the rotary cylinder 23. The rotary motor 22 is, for example, a precision motor such as a servo motor.

The rotary cylinder 23 is rotatably supported by bearings 25A and 25B mounted on the support base 14a. The rotary motor 22 rotates the rotary cylinder 23 via the timing belt 24. The rotary cylinder 23 transmits a rotating force to the head shaft 16, causing the head shaft 16 to rotate. The polishing head PH rotates together with the head shaft 16.

The head shaft 16 is inserted into the rotary cylinder 23 so as to be movable up and down. Therefore, the rotating force acting on the rotary cylinder 23 is transmitted to the head shaft 16, while a vertical force acting on the head shaft 16 is not transmitted to the rotary cylinder 23. A rotary joint 32 is attached to an upper end of the head shaft 16.

The polishing apparatus PA includes an oscillation mechanism 7 that oscillates the oscillation arm 14. The oscillation mechanism 7 includes an arm shaft 12 that supports the oscillation arm 14, and an oscillation motor 20 that oscillates the oscillation arm 14 via the arm shaft 12. The oscillation motor 20 is, for example, a precision motor such as a servo motor. The oscillation motor 20 oscillates the oscillation arm 14 via the arm shaft 12 by driving the oscillation motor 20. In this manner, the oscillation arm 14 is configured to be rotatable around the arm shaft 12.

The polishing apparatus PA includes a plurality of fluid lines 33, 77, and 88 extending to the

polishing head PH through the rotary joint 32. The fluid lines 33, 77, and 88 are coupled to a pressure regulator 36. The pressure regulator 36 is configured to regulate a pressure of the fluid supplied to the polishing head PH through the fluid lines 33, 77, and 88. An example of the fluid supplied includes nitrogen gas and clean dry air.

The polishing apparatus PA includes a control device 10 that controls the operations of the components of the polishing apparatus PA (e.g., the polishing table 2, the polishing head PH, the dresser 41, the polishing liquid supply nozzle 3, etc.). The control device 10 includes a storage unit 10a that stores a program, and a calculation unit 10b that executes calculations according to instructions included in the program.

The storage unit 10a includes a main storage device such as a RAM, and an auxiliary storage device such as a hard disk drive (HDD), a solid state drive (SSD), etc. An example of the calculation unit 10b includes a CPU (Central Processing Unit) or a GPU (Graphics Processing Unit).

The control device 10 is composed of at least one computer. The computer may be one server or multiple servers. The control device 10 may be an edge server, a cloud server connected to a communication network such as the Internet or a local area network, or a fog computing device (gateway, fog server, router, etc.) installed in the network. The control device 10 may be multiple servers connected by a communication network such as the Internet or a local area network. For example, the control device 10 may be a combination of an edge server and a cloud server.

The control device 10 is electrically connected to the pressure regulator 36. Therefore, the control device 10 is configured to operate the pressure regulator 36 to regulate the pressure of the fluid supplied to the polishing head PH (particularly, the elastic membrane 100) through the fluid lines 33, 77, and 88.

The polishing apparatus PA includes a film thickness sensor ES arranged below the polishing table 2. The film thickness sensor ES is configured to detect a film thickness signal that changes in accordance with the film thickness of the wafer W. An example of the film thickness sensor ES includes an optical sensor or an eddy current sensor.

In one embodiment, the film thickness sensor ES may be embedded in the polishing table 2. The film thickness sensor ES is electrically connected to the control device 10 and configured to send a film thickness signal detected by the film thickness sensor ES to the control device 10. The control device 10 measures the film thickness of the wafer W based on the film thickness signal, and terminates polishing of the wafer W based on the film thickness of the wafer W.

A process of polishing the wafer W is as follows. While rotating the polishing table 2 and the polishing head PH, the polishing liquid is supplied from the polishing liquid supply nozzle 3 onto the polishing surface 1a of the polishing pad 1. With the polishing liquid presents on the polishing surface 1a, the polishing head PH presses the wafer W against the polishing surface 1a while rotating the wafer W. As a result, the surface of the wafer W is polished by a mechanical action of the abrasive grains contained in the polishing liquid and a chemical action of the polishing liquid.

During polishing of the wafer W, the control device 10 acquires a film thickness signal detected by the film thickness sensor ES, and measures the film thickness of the wafer W based on the acquired polishing signal. Based on the measured film thickness, the control device 10 controls a polishing operation of the wafer W. When the film thickness of the wafer W reaches a target film thickness, the control device 10 operates the polishing head PH to terminate polishing of the wafer W.

Generally, an elastic membrane has a large number of partition walls for forming divided pressure chambers. Such an elastic membrane is difficult to stretch, especially near the partition walls, and may not be able to uniformly transmit the pressure in the pressure chamber to the wafer W. As a result, the polishing head PH may not be able to apply an appropriate pressing force to the wafer W, which may adversely affect a uniformity of the wafer W. Therefore, in this embodiment, the elastic membrane 100 has a structure that can improve the stretchability. Structures of the elastic membrane 100 will be described below with reference to the drawings.

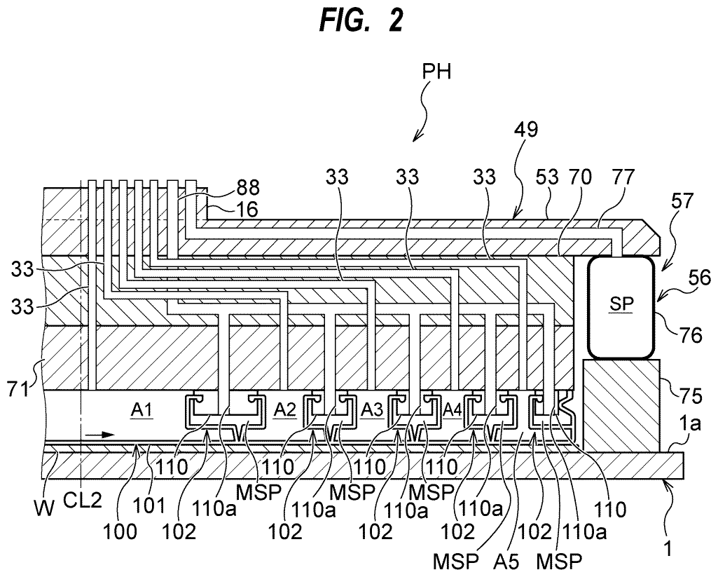

FIG. 2 is an enlarged cross-sectional view showing an embodiment of the polishing head. As shown in FIG. 2, the polishing head PH includes a head body 49, a retaining ring mechanism 57 for preventing the wafer W from jumping out, and an elastic membrane 100 arranged below the head body 49 and for holding the wafer W.

The head body 49 includes a circular flange portion 53 connected to the head shaft 16, a spacer 70 attached to a lower surface of the flange portion 53, and a carrier (base plate) 71 attached to a lower surface of the spacer 70. The carrier 71 is coupled to the flange portion 53 via the spacer 70, and the flange portion 53, the spacer 70, and the carrier 71 rotate together and move up and down.

The retaining ring mechanism 57 includes a retaining ring 75 that surrounds the wafer W, and a retaining ring pressing mechanism 56 that is arranged above the retaining ring 75. The retaining ring 75 is arranged so as to surround a peripheral portion of the wafer W, and is capable of contacting the polishing surface la of the polishing pad 1. The retaining ring 75 prevents the wafer W from jumping out of the polishing head PH during polishing of the wafer W.

The retaining ring 75 is configured to be able to move up and down independently of the flange portion 53 by an operation of the retaining ring pressing mechanism 56. The retaining ring pressing mechanism 56 includes an annular rolling diaphragm 76 and a fluid line 77 that supplies a fluid (e.g., air) to the rolling diaphragm 76.

The rolling diaphragm 76 has a retaining ring pressure chamber SP formed therein. The fluid line 77 passes through the flange portion 53 and communicates with the retaining ring pressure chamber SP. Therefore, when the fluid is supplied to the retaining ring pressure chamber SP through the fluid line 77, the rolling diaphragm 76 presses down on the retaining ring 75. As the retaining ring 75 is pressed down, it is pressed against the polishing surface la of the polishing pad 1.

On the other hand, by forming a vacuum in the retaining ring pressure chamber SP through the fluid line 77, the rolling diaphragm 76 lifts the retaining ring 75. The retaining ring pressure chamber SP is also connected to an atmosphere release mechanism (not shown). Therefore, the retaining ring pressure chamber SP can be opened to the atmosphere.

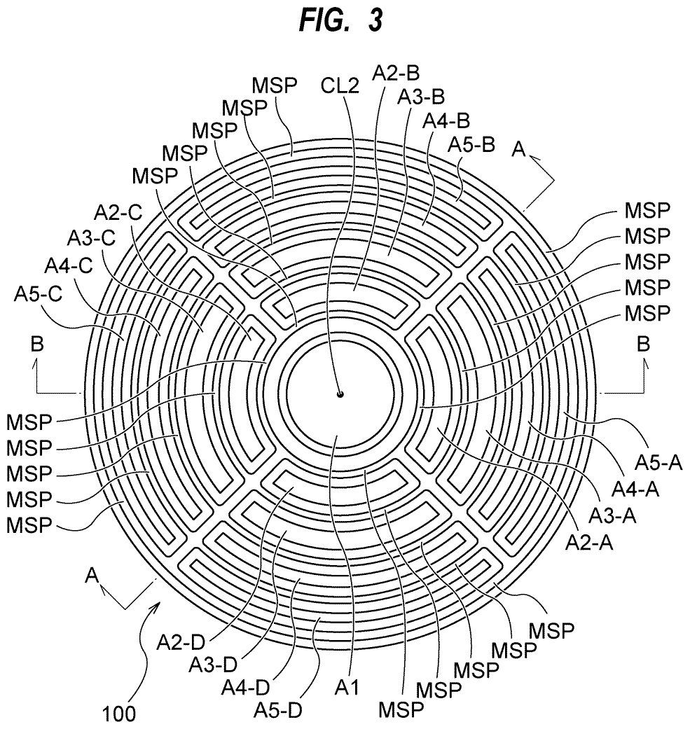

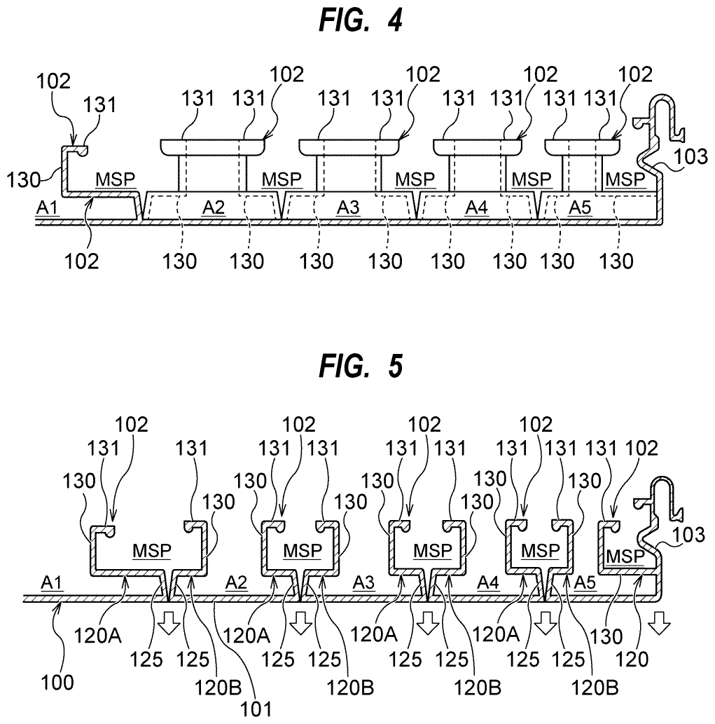

FIG. 3 is a plan view showing one embodiment of the elastic membrane. FIG. 4 is a partial cross-sectional view taken along a line A-A in FIG. 3. FIG. 5 is a partial cross-sectional view taken along a line B-B in FIG. 3. The elastic membrane 100 is made of a flexible rubber material having excellent strength and durability, such as ethylene propylene rubber (EPDM), polyurethane rubber, or silicone rubber.

The elastic membrane 100 has a planar pressing portion 101 that presses the wafer W, a plurality of partition walls 102 that extend from the pressing portion 101 toward the head body 49, and a peripheral wall 103 that is connected to an outermost partition wall 102 of the partition walls 102 and that constitutes an outer shape of the elastic membrane 100. The pressing portion 101, the partition walls 102, and the peripheral wall 103 are integrally molded members.

The elastic membrane 100 has a pressure chamber A1 formed in a center of the elastic membrane 100 by the pressing portion 101, the partition walls 102 and the peripheral wall 103, and a plurality of pressure chambers A2 to A5 divided along the radial and circumferential directions of the wafer W (i.e., the polishing head PH).

The pressure chamber A1 is arranged along the central axis CL2 of the head shaft 16. In the embodiment shown in FIG. 3, the pressure chamber A1 has a circular shape when viewed from the head shaft 16 side (i.e., from above). In one embodiment, the pressure chamber A1 may have a polygonal shape.

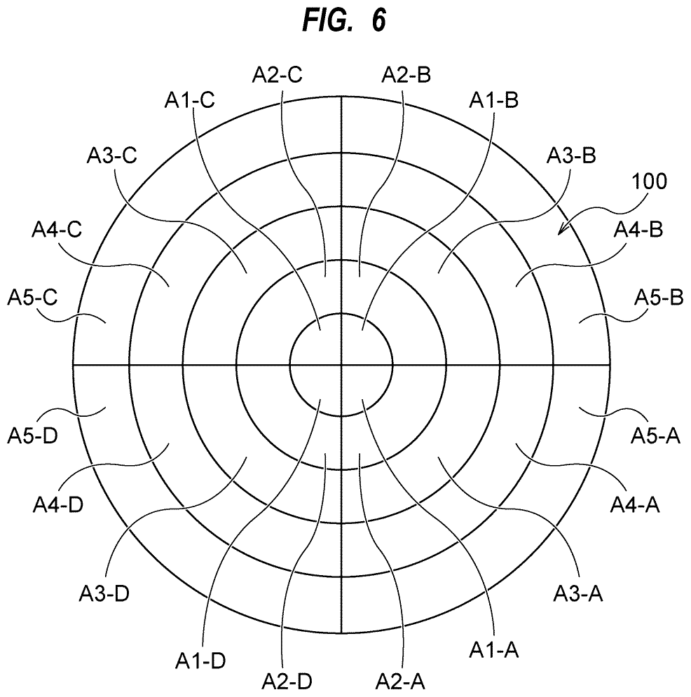

FIG. 6 is a view showing another embodiment of the elastic membrane. As shown in FIG. 6, the pressure chamber A1 may have a plurality of pressure chambers A1-A, A1-B, A1-C, and A1-D each having a sector shape when viewed from above. These pressure chambers A1-A to A1-D are arranged at equal intervals along the circumferential direction of the elastic membrane 100.

As shown in FIG. 6 (and FIG. 3), the pressure chambers A2 to A5 are arranged around the pressure chamber A1 and are arranged at equal intervals along the circumferential direction of elastic membrane 100. More specifically, the pressure chamber A2 is made up of a plurality of pressure chambers A2-A, A2-B, A2-C, and A2-D that surround the pressure chamber A1. The pressure chamber A3 is made up of a plurality of pressure chambers A3-A, A3-B, A3-C, and A3-D that surround the pressure chamber A2.

Similarly, the pressure chamber A4 is made up of a plurality of pressure chambers A4-A, A4-B, A4-C, and A4-D that surround the pressure chamber A3. The pressure chamber A5 is made up of a plurality of pressure chambers A5-A, A5-B, A5-C, and A5-D that surround the pressure chamber A4.

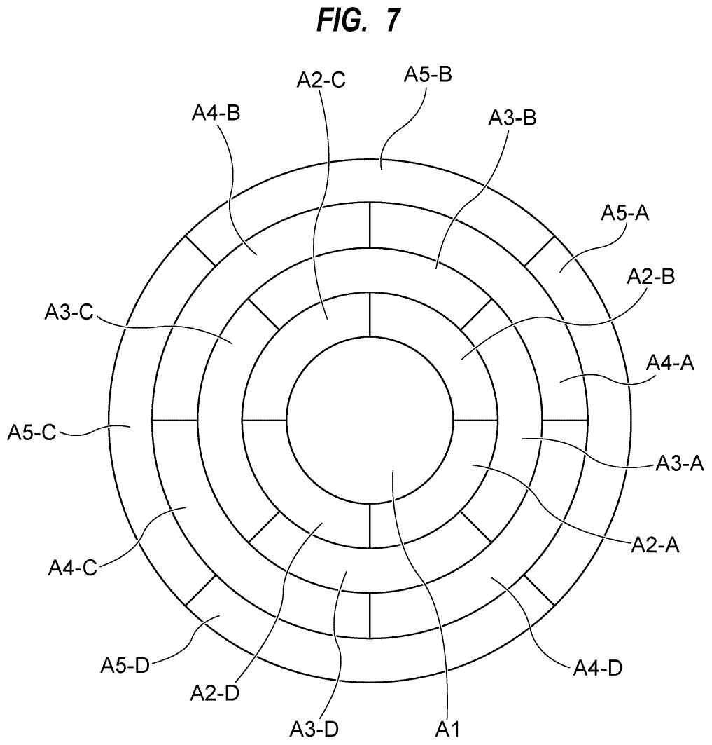

FIG. 7 is a view showing another embodiment of the elastic membrane. In the embodiment shown in FIG. 6, the pressure chambers constituting the pressure chambers A2 to A5 surrounding the pressure chamber A1 are linearly (i.e., on a straight line) arranged along the radial direction of the elastic membrane 100. In one embodiment, as shown in FIG. 7, the pressure chambers constituting the pressure chambers A2 to A5 arranged along the radial direction of the elastic membrane 100 may be arranged offset by a predetermined rotation angle (a rotation angle of 45 degrees in the embodiment shown in FIG. 7) along the circumferential direction of the elastic membrane 100.

The fluid line 33 passes through the head body 49 (more specifically, the flange portion 53, the spacer 70, and the carrier 71) and communicates with each of the pressure chambers A1 to A5 (see FIG. 2). Therefore, the control device 10 can individually control the pressure of the fluid supplied to the pressure chambers A1 to A5 through the fluid line 33 by operating the pressure regulator 36.

Each of the pressure chambers A1 to A5 is connected to a vacuum line (not shown). The control device 10 is configured to control an operation of a vacuum pump (not shown) connected to the vacuum line. Thus, the control device 10 can create a vacuum in each of the pressure chambers A1 to A5 by operating the vacuum pump.

Each of the pressure chambers A1 to A5 is also connected to an atmosphere release mechanism (not shown), so that each of the pressure chambers A1 to A5 can be opened to the atmosphere.

Since the partition walls 102 basically have the same structure, structures of a single partition wall 102 will be described below with reference to FIG. 5.

As shown in FIG. 5, the partition wall 102 has a bulging structure that bulges in a direction away from the pressing portion 101. The partition wall 102 having such a bulging structure forms a pressurizing chamber MSP for applying a pressing force to the pressing portion 101.

The pressurizing chamber MSP is formed between the pressure chambers A1 to A5 that are adjacent to each other along the radial direction of the elastic membrane 100. More specifically, the pressurizing chambers MSP are arranged between the pressure chambers A1 and A2, between the pressure chambers A2 and A3, between the pressure chambers A3 and A4, and between the pressure chambers A4 and A5. The pressurizing chamber MSP arranged on an outermost side of the elastic membrane 100 is adjacent to the pressurizing chamber MSP arranged between the pressure chambers A4 and A5.

In this manner, among the pressure chambers A1 to A5, adjacent pressure chambers are arranged on both sides of the pressurizing chamber MSP. The pressurizing chamber MSP is formed above the pressing portion 101, that is, above the pressure chambers A1 to A5.

The polishing apparatus PA includes a fluid line 88 extending to the pressurizing chamber MSP through the rotary joint 32 (see FIG. 2). The fluid line 88 is coupled to the pressure regulator 36. Therefore, the control device 10 can individually control the pressure of the fluid supplied to the pressurizing chamber MSP through the fluid line 88 by operating the pressure regulator 36.

The pressurizing chamber MSP is connected to a vacuum line (not shown). The control device 10 is configured to control an operation of a vacuum pump (not shown) connected to the vacuum line. Thus, the control device 10 can create a vacuum in the pressurizing chamber MSP. The pressurizing chamber MSP is also connected to an atmosphere release mechanism (not shown). Thus, the pressurizing chamber MSP can be released to the atmosphere.

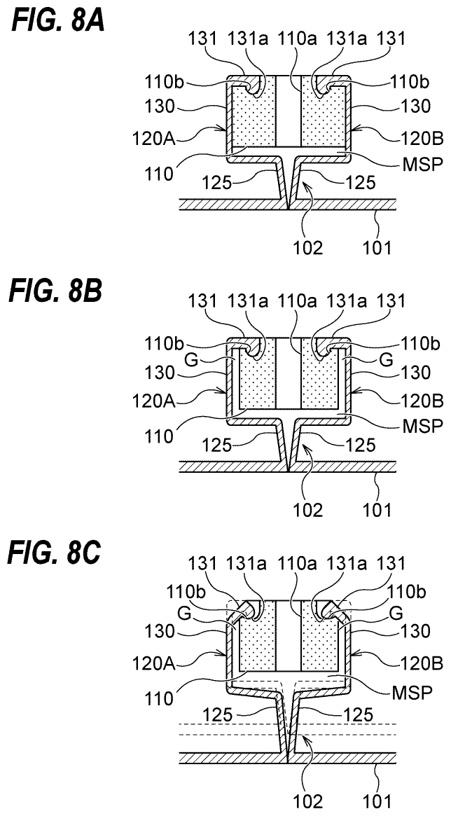

FIG. 8A is a view showing an example of the partition wall mounted on a partition wall holder, FIG. 8B is a view showing another example of the partition wall mounted on the partition wall holder, and FIG. 8C is a view showing a state in which the partition wall mounted on the partition wall holder is tilted.

As shown in FIG. 8A (and FIG. 2), the carrier 71 includes partition wall holders 110, the number of which corresponds to the number of partition walls 102. The partition wall holder 110 is fixed to a lower surface of the carrier 71, and has a communication hole 110a connected to the fluid line 88 (and the vacuum line). Thus, the pressurizing chamber MSP communicates with the fluid line 88 through the communication hole 110a of the partition wall holder 110.

The partition wall 102 has a first wall portion 120A and a second wall portion 120B that form a bulging structure. The first wall portions 120A and 120B are arranged adjacent to each other and symmetrically. Since the first wall portions 120A and 120B basically have the same structure, hereinafter the first wall portions 120A and 120B may be referred to as a wall portion 120 without any particular distinction.

The wall portion 120 has a base end portion 125 connected to the pressing portion 101, a wide portion 130 connected to the base end portion 125 and arranged spaced apart (adjacent) from the pressing portion 101, and a clamp portion 131 connected to the wide portion 130 and held by the partition wall holder 110. The base end portion 125, the wide portion 130, and the clamp portion 131 are integrally configured.

Each of the first wall portions 120A, 120B has the base end portion 125, the wide portion 130, and the clamp portion 131. The adjacent base end portions 125 are connected to each other at the pressing portion 101. These base end portions 125 extend in directions away from each other from the pressing portion 101 and have a V-shaped cross-section. In other words, the first wall portions 120A, 120B have V-shaped cross-sections approaching each other toward the pressing portion 101, and are connected to each other at the pressing portion 101.

The adjacent wide portions 130 have wide shapes that are spaced apart from each other. The partition wall holder 110 is sandwiched between these wide portions 130. The adjacent clamp portions 131 are close to each other so as to cover the partition wall holder 110, and are fixed to an upper end of the partition wall holder 110.

More specifically, the clamp portion 131 has a protrusion 131a that protrudes toward the pressing portion 101. The partition wall holder 110 has a fitting portion 110b having a shape corresponding to the protrusion 131a. The fitting portion 110b is formed at an upper end of the partition wall holder 110.

By mounting the protrusion 131a to the fitting portion 110b, the partition wall 102 as a whole is firmly held by the partition wall holder 110. In the embodiment shown in FIG. 8A, the partition wall holder 110 as a whole is arranged in the pressurizing chamber MSP, but in one embodiment, at least a part of the partition wall holder 110 may be arranged in the pressurizing chamber MSP. In this case, the fitting portion 110b does not necessarily have to be formed at the upper end of the partition wall holder 110.

When the partition wall 102 is attached to the partition wall holder 110, the communication hole 110a of the partition wall holder 110 communicates with the pressurizing chamber MSP of the partition wall 102. In this state, by supplying the fluid to the pressurizing chamber MSP through the fluid line 88, the partition wall 102 elastically deforms (expands) as a whole.

According to this embodiment, the partition wall 102 having the bulging structure is configured to apply a pressing force to the pressing portion 101 by its elastic deformation (see arrows in FIG. 5). Therefore, the elastic membrane 100 can improve its stretchability, particularly the stretchability of the pressing portion 101.

Japanese laid-open patent publication No. 2005-223322 discloses a flexible membrane having an air pressure introduction portion. The flexible membrane is supported by a partition wall support portion that supports the partition wall, and the partition wall support portion is formed by a part of a supporter as a component of a polishing head. Thus, in Japanese laid-open patent publication No. 2005-223322, an auxiliary air pressure region is formed by the flexible membrane and the partition wall support portion of the supporter.

On the other hand, in this embodiment, the pressurizing chamber MSP is configured with a partition wall 102 having the bulging structure. Therefore, by supplying the fluid to the pressurizing chamber MSP, the partition wall 102 as a whole can be largely elastically deformed, and the pressing force against the pressing portion 101 can be applied more actively.

In this manner, the partition 102 having the bulging structure can greatly contribute to improving the elasticity of the pressing portion 101. Japanese laid-open patent publication No. 2005-223322 does not disclose a flexible membrane having such a structure, and the flexible membrane of Japanese laid-open patent publication No. 2005-223322 has a structure different from that of the elastic membrane 100 according to the present embodiment.

In this embodiment, the partition wall 102 is entirely made of an elastic material, including the wide portion 130 and the clamp portion 131. Therefore, the polishing head PH can be assembled simply by attaching the partition wall 102 to the partition wall holder 110 so as to cover the partition wall holder 110. Furthermore, by configuring the wide portion 130 to be elastically deformable, even if the elastic membrane 100 has some assembly error, the elastic membrane 100 can absorb the assembly error.

Furthermore, in this embodiment, the polishing head PH has a structure in which the partition wall holder 110 is sandwiched by the elastic membrane 100. With such a structure, the polishing head PH can improve a sealing performance of the pressurizing chamber MSP and can prevent the liquid from entering the pressurizing chamber MSP. In this embodiment, the elastic membrane 100 has an elastically deformable wide portion 130. Therefore, the elastic membrane 100 can improve an assembly and a sealing performance of the polishing head PH.

If the partition wall 102 is made of a hard material or if a distance between the elastic membrane 100 and the wafer W (i.e., a membrane height) is large, even if the fluid is supplied to the pressurizing chamber MSP, the partition wall 102 may not be able to sufficiently improve the elasticity of the pressing portion 101. In this embodiment, the elastic membrane 100 has the partition wall 102 that is elastically deformable, and therefore the partition wall 102 can be greatly expanded and contracted.

The elastic membrane 100 aims to improve a uniformity of the wafer W by compensating for a pressure loss applied to the wafer W from the pressing portion 101. According to this embodiment, the elastic membrane 100 having the partition wall 102 can sufficiently compensate for the pressure loss applied to the wafer W.

If the elastic membrane 100 has a high rubber hardness, the elastic membrane 100 may not expand or contract sufficiently, which may adversely affect the uniformity of the wafer W. Therefore, it is necessary to adjust the rubber hardness of the elastic membrane 100 by changing the thickness and the shape of the elastic membrane 100. However, in this case, it is necessary to prepare multiple molds for manufacturing the elastic membranes 100 having various shapes, which is not realistic because it requires a lot of cost and time.

As shown in FIGS. 8B and 8C, the polishing head PH may have a widthwise gap G formed between the wall portion 120 and the partition wall holder 110. The widthwise gap G is formed between the wide portion 130 and the partition wall holder 110.

By forming the widthwise gap G, the wall portion 120 can deform more elastically without being hindered by the partition wall holder 110 (see FIG. 8C). Therefore, there is no need to change the thickness or the shape of the elastic membrane 100, and the cost required for manufacturing the elastic membrane 100 can be reduced.

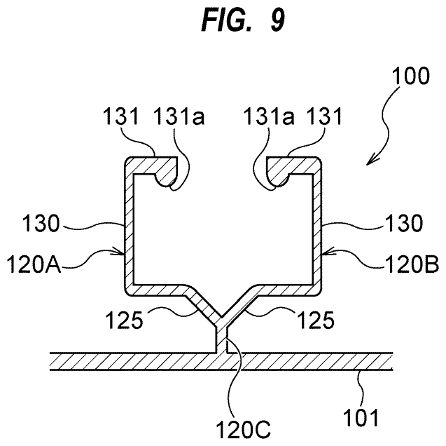

FIG. 9 is a view showing another embodiment of the partition wall. As shown in FIG. 9, the partition wall 102 has a third wall portion 120C connected to the first wall portions 120A and 120B. The third wall portion 120C extends from a connection portion of the first wall portions 120A and 120B toward the pressing portion 101.

The third wall portion 120C extends perpendicular to the pressing portion 101. The third wall portion 120C has one end connected to the pressing portion 101 and the other end connected to the base end portions 125, 125 of the first wall portions 120A, 120B. With this structure, the partition wall 102 has a Y-shaped cross section.

In one embodiment, the elastic membrane 100 may have a plurality of partition walls 102, including a partition wall 102 having a V-shaped cross-section (see FIGS. 1 to 8) and a partition wall 102 having a Y-shaped cross-section (see FIG. 9).

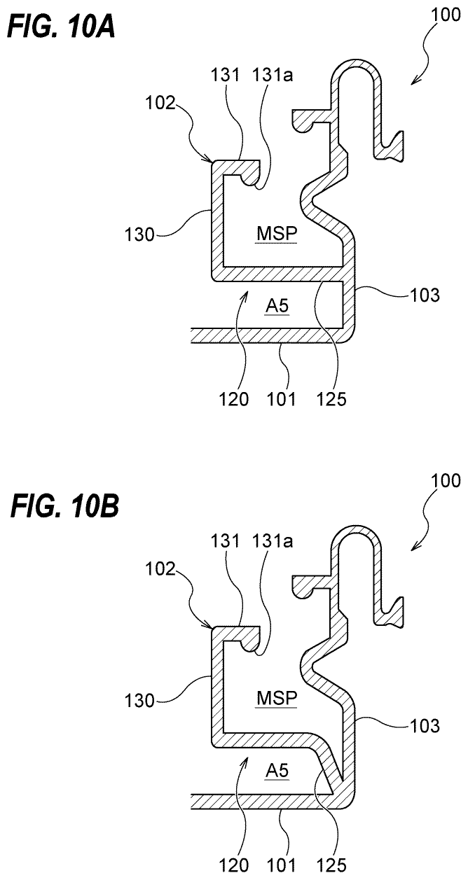

FIG. 10A is a view showing an embodiment of the peripheral wall of the elastic membrane, and FIG. 10B is a view showing another embodiment of the peripheral wall. As shown in FIG. 10A, the partition wall 102 constituting the pressurizing chamber MSP formed in an upper portion of the pressure chamber A5 is arranged adjacent to the peripheral wall 103, and has the wall portion 120 connected to the peripheral wall 103. Hereinafter, the wall portion 120 connected to the peripheral wall 103 may be referred to as a peripheral wall side wall portion 120. The partition wall 102 having the peripheral wall side wall portion 120 may be referred to as a peripheral wall side partition wall 102.

As shown in FIG. 10A, the peripheral wall side wall portion 120 has a base end portion 125 connected to the peripheral wall 103, and a wide portion 130 and a clamp portion 131 connected to the base end portion 125. The base end portion 125 extends parallel to the pressing portion 101. By supplying the fluid to the pressurizing chamber MSP formed by the partition wall 102 having the bulging structure and the peripheral wall 103, the peripheral wall side partition wall 102 applies the pressing force to the pressing portion 101 via the peripheral wall 103.

As shown in FIG. 10B, the base end portion 125 of the peripheral wall side wall portion 120 may extend at an angle relative to the pressing portion 101. More specifically, the base end portion 125 extends obliquely downward toward the pressing portion 101, and is connected to a connection portion (or the pressing portion 101) between the pressing portion 101 and the peripheral wall 103. With this configuration, the peripheral wall side partition wall 102 can apply the pressing force to the pressing portion 101 by supplying the fluid to the pressurizing chamber MSP.

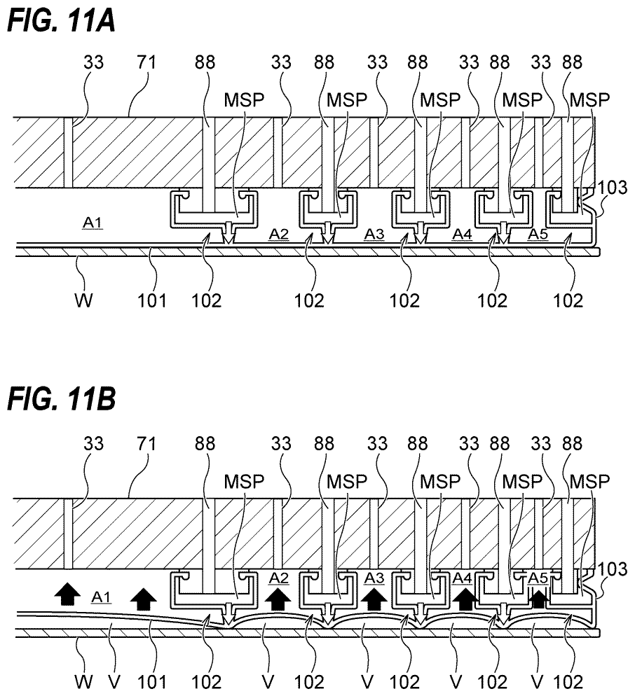

FIGS. 11A and 11B are views showing an operation of the polishing head to suction and hold the wafer. First, the fluid is supplied to the pressurizing chamber MSP to bring the entire pressing portion 101 into close contact with the wafer W (see FIG. 11A). In this state, a vacuum is created in each of the pressure chambers A1 to A5 to form a suction space V on the lower surface of the pressing portion 101 (see FIG. 11B). The suction space V corresponds to a suction cup formed by the pressing portion 101.

In this manner, by forming the suction space V on the lower surface of the pressing portion 101, the polishing head PH can suction and hold the wafer W (suction process). In this state, the polishing head PH is transported to a predetermined polishing position (i.e., above the polishing pad 1) and starts polishing the wafer W.

At the start of polishing the wafer W, the polishing head PH presses the wafer W against the polishing pad 1 by supplying the fluid to the pressure chambers A1 to A5, and applies the pressing force to the pressing portion 101 through the partition wall 102 by supplying the fluid to the pressurizing chamber MSP.

Basically, the pressure of the fluid supplied to the pressurizing chamber MSP is arbitrarily determined. In one embodiment, in order to achieve a purpose of improving the elasticity of the pressing portion 101, the pressure of the fluid supplied to the pressurizing chamber MSP may be determined to be a lowest pressure among the pressure chambers A1 to A5.

In one embodiment, in order to apply the pressing force to the pressing portion 101 directly below the partition wall 102 that constitutes the pressurizing chamber MSP, the pressure of the fluid supplied to the pressurizing chamber MSP may be determined to be equal to or greater than the pressure of the fluid supplied to the pressure chambers A1 to A5.

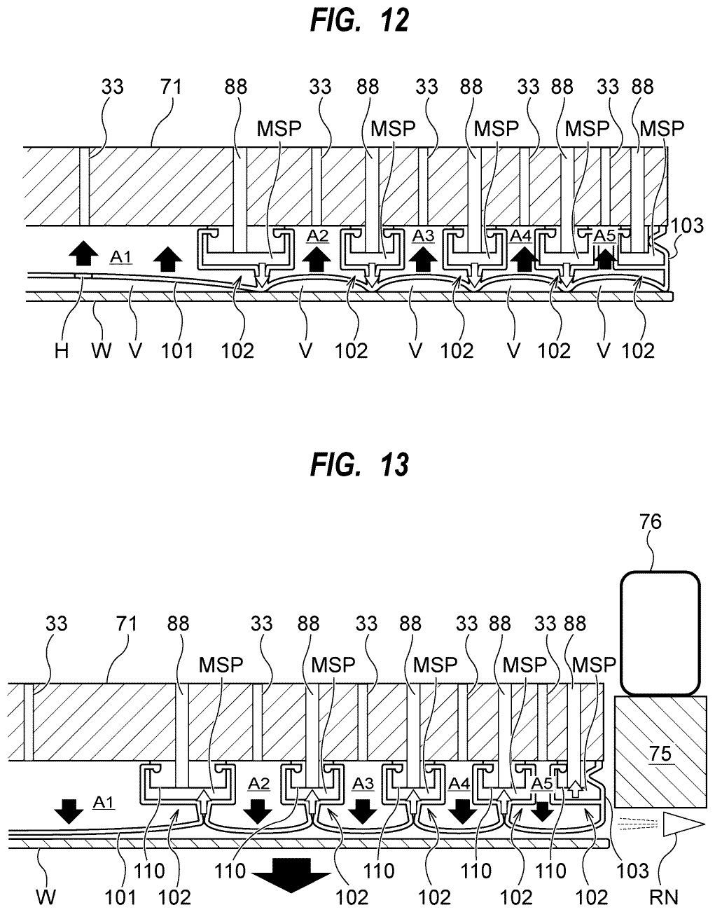

FIG. 12 is a view showing another embodiment of the elastic membrane. As shown in FIG. 12, the elastic membrane 100 may have a suction hole H formed in the pressing portion 101. In the embodiment shown in FIG. 12, the suction hole H is formed in the pressing portion 101 that forms the pressure chamber A1.

By forming a vacuum in the pressure chamber A1 while the wafer W is in close contact with the pressing portion 101, the wafer W is sucked to the pressing portion 101 through the suction hole H. In this manner, the polishing head PH may suck and hold the wafer W through the suction hole H while forming the suction space V. By forming the suction hole H, moisture present between the wafer W and the pressing portion 101 can be removed through the suction hole H.

After polishing of the wafer W is completed, the polishing head PH carries out the above-described suction step to transport the wafer W to a predetermined position for the next process while suction-holding the wafer W. The polishing head PH is configured to release the wafer W that has been transported to the position for the next process.

FIG. 13 is a view showing an operation of the polishing head to release the wafer W. As shown in FIG. 13, the control device 10 is configured to release the wafer W from the elastic membrane 100 by forming the vacuum in the pressurizing chamber MSP and supplying the fluid to the pressure chambers A1 to A5 (release process).

By the above-described release process, the pressing portion 101 immediately below the partition wall 102 constituting the pressurizing chamber MSP approaches the carrier 71, while the pressing portions 101 forming the respective pressure chambers A1 to A5 expand downward. In this manner, the polishing head PH exposes a gap between the pressing portion 101 and the wafer W.

As shown in FIG. 13, the polishing apparatus PA includes a release nozzle RN that sprays a fluid toward the gap between the pressing portion 101 and the wafer W. An example of the fluid sprayed from the release nozzle RN includes deionized water (DIW) and nitrogen gas. After the release process of the wafer W is performed, the wafer W is reliably released from the polishing head PH by spraying the fluid from the release nozzle RN toward the gap between the pressing portion 101 and the wafer W.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

What is claimed is:

1. An elastic membrane applicable to a polishing head for polishing a substrate, comprising:
a pressing portion configured to press against the substrate; and
a partition wall having a bulging structure configured to form a pressurizing chamber for applying a pressing force to the pressing portion.

2. The elastic membrane according to claim 1,
wherein the partition wall has a first wall portion and a second wall portion configured to form the bulge structure, and
wherein the first wall portion and the second wall portion have:
a wide portion configured to be spaced apart from each other; and
a clamp portion configured to be connected to the wide portion and be close to each other.

3. The elastic membrane according to claim 1,
wherein the partition wall has a first wall portion and a second wall portion having a V-shaped cross-section configured to be close to each other toward the pressing portion, and
wherein the first wall portion and the second wall portion are connected to each other at the pressing portion.

4. The elastic membrane according to claim 1,
wherein the partition wall has a first wall portion, a second wall portion, and a third wall portion having a Y-shaped cross section, and
wherein the third wall portion is connected to the first wall portion and the second wall portion, and extends from a connection portion between the first wall portion and the second wall portion toward the pressing portion.

5. The elastic membrane according to claim 1,
wherein the partition wall has a first pressure chamber and a second pressure chamber arranged on both sides of the pressurizing chamber, and
wherein the pressurizing chamber is arranged above the first pressure chamber and the second pressure chamber.

6. The elastic membrane according to claim 1,
wherein the elastic membrane has a peripheral wall constituting an outer shape of the elastic membrane, and
wherein the partition wall has a peripheral wall side wall portion being arranged adjacent to the peripheral wall and extending at an angle relative to the pressing portion.

7. A polishing head comprising:
an elastic membrane according to claim 1; and
a head body configured to hold the elastic membrane.

8. The polishing head according to claim 7,
wherein the head body comprises a partition wall holder configured to hold the partition wall, and
wherein at least a portion of the partition wall holder is arranged in the pressurizing chamber.

9. The polishing head according to claim 8,
wherein the polishing head has a widthwise gap formed between the partition wall and the partition wall holder.

10. A polishing method comprising:
holding a substrate by an elastic membrane configured to press against the substrate;
supplying a fluid to a pressure chamber formed by a pressing portion configured to press against the substrate, while holding the substrate, to press the substrate against a polishing pad; and
supplying a fluid to a pressurizing chamber formed by a partition wall having a bulge structure, to apply a pressing force to the pressing portion.

11. The polishing method according to claim 10,
wherein holding the substrate comprises supplying a fluid to the pressurizing chamber and forming a vacuum in the pressure chamber to form a suction space on a lower surface of the pressing portion and suck the substrate.

12. The polishing method according to claim 10,
wherein the polishing method comprises, after polishing of the substrate, forming a vacuum in the pressurizing chamber and supplying a fluid to the pressure chamber to release the substrate from the elastic membrane.

13. The polishing method according to claim 10,
wherein the partition wall has a first wall portion and a second wall portion configured to form the bulging structure, and
wherein the first wall portion and the second wall portion have:
a wide portion configured to be spaced apart from each other; and
a clamp portion configured to be connected to the wide portion and be close to each other.

14. The polishing method according to claim 10,
wherein the partition wall has a first wall portion and a second wall portion having a V-shaped cross-section configured to be close to each other toward the pressing portion, and
wherein the first wall portion and the second wall portion are connected to each other at the pressing portion.

15. The polishing method according to claim 10,
wherein the partition wall has a first wall portion, a second wall portion, and a third wall portion having a Y-shaped cross section, and
wherein the third wall portion is connected to the first wall portion and the second wall portion, and extends from a connection portion between the first wall portion and the second wall portion toward the pressing portion.

16. The polishing method according to claim 10,
wherein the elastic membrane has a peripheral wall constituting an outer shape of the elastic membrane, and
wherein the partition wall has a peripheral wall side wall portion being arranged adjacent to the peripheral wall and extending at an angle relative to the pressing portion.
